(19) United States
(12) Patent Application Publication
(10) Pub. No.: US 2020/0396853 A1
(43) Pub. Date: Dec. 17, 2020

(54) DISPLAY MODULE AND DISPLAY DEVICE

(71) Applicants: BOE Technology Group Co., Ltd., Beijing (CN); Hefei BOE Optoelectronics Technology Co., Ltd., Hefei, Anhui (CN)

(72) Inventors: Zhixiang FANG, Beijing (CN); Jian HE, Beijing (CN)

(21) Appl. No.: 16/074,299

(22) PCT Filed: Jan. 25, 2018
(86) PCT No.: PCT/CN2018/074147

§ 371 Date: Jul. 31, 2018

(30) Foreign Application Priority Data
May 9, 2017 (CN) 201710320371.1

(51) Int. Cl. H05K 5/04; G06F 3/041; H05K 5/00; F21V 8/00; G02F 1/1333; G02F 1/1343

(52) U.S. Cl. CPC H05K 5/04; G06F 3/0414; H05K 5/0017; G02F 1/13439; G02F 1/133308; G02F 1/13338; G02B 6/0055

(57) ABSTRACT

The application provides a display module and a display device. A support structure configured to support a force sensing layer is additionally arranged in an accommodating chamber defined by a metal frame, and a gap is provided between the force sensing layer and the metal frame, the gap varies with a varying force applied to the force sensing layer, so that a capacitance between the force sensing layer and the metal frame can vary under the action of a touch force to thereby perform a force touch function in the display module so as to simplify a process, to facilitate the integration of the industry, and to improve a good yield as a whole. Furthermore the force sensing layer is arranged on the backside of a display panel without affecting the brightness of the display module

This application is a National Stage of International Application No. PCT/CN2018/074147, filed Jan. 25, 2018, which claims the priority to Chinese Patent Application No. 201710320371.1, filed with the Chinese Patent Office on May 9, 2017, and entitled “Display module, display panel and display device”, the content of which is hereby incorporated by reference in its entirety.

### FIELD

The present application relates to the field of display technologies, and particularly to a display module, a display panel, and a display device.

### BACKGROUND

At present, in the existing display module, in order to perform a force touch function in the prior art, a force sensing layer (ITO sensor) is arranged outside the display module. This arrangement increases the thickness of the product, but also hinders the product from being made light-weighted and thin, and a process flow thereof is more complicated, thus discouraging the integration of the industry, and resulting in a high cost.

### SUMMARY

An embodiment of the application provides a display module including: a metal frame, a display panel in an accommodating chamber defined by the metal frame, a support structure located between a backside of the display panel and a bottom side of the metal frame, and a force sensing layer located on a side of the support structure facing the display panel, wherein: a gap is provided between the force sensing layer and the metal frame, and the gap varies with a varying force applied to the force sensing layer.

Optionally in the display module above according to the embodiment of the application, the display module further includes: a mode frame located in the accommodating chamber defined by the metal frame, and configured to support the display panel, the mode frame has a portion extending to a display area of the display panel, and the support structure includes the portion of the mode frame extending to the display area.

Optionally in the display module above according to the embodiment of the application, a gap is arranged between the portion of the mode frame extending to the display area and the bottom side of the metal frame.

Optionally in the display module above according to the embodiment of the application, the portion of the mode frame extending to the display area is a hollow structure.

Optionally in the display module above according to the embodiment of the application, the hollow structure can be a grid-like hollow structure, or a strip-like hollow structure.

Optionally in the display module above according to the embodiment of the application, a proportion of the hollow structure per unit area at a center of the display area is less than the proportion of the hollow structure per unit area on an edge of the display area.

Optionally in the display module above according to the embodiment of the application, a thickness of the portion of the mode frame extending to the display area is less than or equal to 0.1 mm.

Optionally in the display module above according to the embodiment of the application, the support structure includes at least one support body independent of each other located between the force sensing layer and the bottom side of the metal frame.

Optionally in the display module above according to the embodiment of the application, the number of support bodies per unit area at a center of the display area is more than the number of hollow structures per unit area on an edge of the display area.

Optionally in the display module above according to the embodiment of the application, the force sensing layer includes a plurality of sense electrodes, which are blocks and distributed in an array.

Optionally in the display module above according to the embodiment of the application, the sense electrodes are transparent electrically-conductive films (ITO).

Optionally in the display module above according to the embodiment of the application, the metal frame is grounded.

Optionally in the display module above according to the embodiment of the application, the display panel includes a liquid crystal display screen, and a backlight module located on a backside of the liquid crystal display screen, and the force sensing layer is located on a side of the backlight module facing the support structure.

Optionally in the display module above according to the embodiment of the application, the backlight module includes a reflecting sheet, a light-guiding plate, and an optical film material stacked on each other, and the force sensing layer is located on a side of the reflecting sheet facing the support structure.

Optionally in the display module above according to the embodiment of the application, the display panel includes a light-emitting display screen, and the force sensing layer is located on a side of a base substrate of the light-emitting display screen facing the support structure.

An embodiment of the application further provides a display device including the display module according to the embodiment of the application.

### BRIEF DESCRIPTION OF THE DRAWINGS

FIG. 1 is a schematic structural diagram of a display module in the related art in a sectional view;

FIG. 2A and FIG. 2B are schematic structural diagrams respectively of a display module according to an embodiment of the application in sectional views;

FIG. 3 is a schematic structural diagram of a force sensing layer in the display module according to the embodiment of the application;

FIG. 4 is a first schematic diagram of a support structure in the display module according to the embodiment of the application;

FIG. 5 is a second schematic diagram of a support structure in the display module according to the embodiment of the application; and

FIG. 6 is a third schematic diagram of a support structure in the display module according to the embodiment of the application.

### DETAILED DESCRIPTION

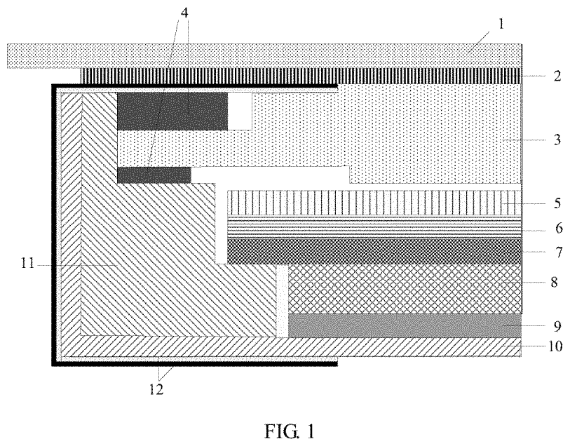

Referring to FIG. 1, the existing display module, e.g., a liquid crystal display module, etc., includes a cover plate 1, optical adhesive 2, a display screen 3 located in a metal frame 10, a buffer material 4, an upper diffusion sheet 5 (Up Diffusion sheet), an upper prism sheet 6 (Prism sheet up), a lower prism sheet 7 (Prism sheet down), a light-guiding plate 8, a reflecting sheet 9, mode frame 11, and sealant 12. In order to perform a force touch function in the existing display module as illustrated in FIG. 1, a force sensing layer (ITO sensor) is arranged outside the display module. This arrangement increases the thickness of the product, but also hinders the product from being made light-weighted and thin, and a process flow thereof is more complicated, thus discouraging the integration of the industry, and resulting in a high cost.

In view of this, an embodiment of the application provides a display module and a display device, where a force sensing layer is arranged in the display module to thereby perform a force touch function in the display module so as to simplify a process, to facilitate the integration of the industry, and to improve a good yield as a whole, without affecting the brightness of the display module.

The technical solutions according to the embodiments of the application will be described below clearly and fully with reference to the drawings in the embodiments of the application, and apparently the embodiments to be described are only a part but not all of the embodiments of the application. Based upon the embodiments here of the application, all the other embodiments which can occur to those ordinarily skilled in the art without any inventive effort shall fall into the scope of the application.

An embodiment of the application provides a display module including: a metal frame, a display panel in an accommodating chamber defined by the metal frame, a support structure located between the backside of the display panel and the bottom side of the metal frame, and a force sensing layer located on the side of the support structure facing the display panel.

A gap is provided between the force sensing layer and the metal frame, and the gap varies with a varying force applied to the force sensing layer.

Specifically in the display module above according to the embodiment of the application, the support structure configured to support the force sensing layer is additionally arranged in the accommodating chamber defined by the metal frame, and some gap between the force sensing layer and the metal frame varies with a varying force applied to the force sensing layer, so that a capacitance between the force sensing layer and the metal frame can vary under the action of a touch force to thereby perform a force touch function in the display module so as to simplify a process, to facilitate the integration of the industry, and to improve a good yield as a whole. Furthermore the force sensing layer is arranged on the backside of the display panel without affecting the brightness of the display module.

Optionally in the display module above according to the embodiment of the application, in order to provide the capacitance between the force sensing layer and the metal frame, the metal frame generally can be grounded as a reference layer (back cover GND) for a force touch, and a variation in charging and discharging current of the force sensing layer due to a variation in capacitance is detected. Or a constant potential can be applied to the force sensing layer, although the embodiment of the application will not be limited thereto.

Specifically in the display module above according to the embodiment of the application, on one hand, the support structure is configured to support the force sensing layer, and on the other hand, while the force sensing layer is being pressed, the support structure shall be so deformed that the gap between the force sensing layer and the metal frame can vary with the varying force applied to the force sensing layer. As for the functions of the support structure above, the support structure can be made of some plastic and rigid material.

Optionally in the display module above according to the embodiment of the application, the display module further includes a mode frame located in the accommodating chamber defined by the metal frame, and configured to support the display panel. The mode frame has a portion extending to a display area of the display panel, and the support structure can include the portion of the mode frame extending to the display area. Stated otherwise, the shape of the existing mode frame is modified so that the portion thereof extending to below the display area acts as the support structure.

Optionally in the display module above according to the embodiment of the application, some gap is provided between the portion of the mode frame extending to the display area and the bottom side of the metal frame. This gap is benefit to effective deformation of the support structure.

At this time the gap between the force sensing layer and the metal frame includes the thickness of the portion of the mode frame extending to the display area, and the gap between the portion of the mode frame extending to the display area and the bottom side of the metal frame. Specifically the height of the gap between the force sensing layer and the metal frame can be set as needed in reality, and generally can range from 0.1 mm to 0.3 mm. The thickness of the portion of the mode frame extending to the display area can be less than or equal to 0.1 mm, and the thinner the better, as long as the mode frame can support the force sensing layer, but also can be deformed under the action of a force.

Optionally the portion of the mode frame extending to the display area can alternatively come into contact with the bottom side of the metal frame, that is, there is no gap between them. Meanwhile, the gap between the force sensing layer and the metal frame is equal to the thickness of the portion of the mode frame extending to the display area.

Optionally in the display module above according to the embodiment of the application, the portion of the mode frame extending to the display area can be a hollow structure, so that the support structure can be better deformed while a force is being applied thereto. Of course, the portion of the mode frame extending to the display area can alternatively be structured in an integral layer, that is, the portion of the mode frame extending to the display area is not limited to hollow structure as long as it can be deformed while a force is being applied thereto.

Optionally in the display module above according to the embodiment of the application, the hollow structure can be a grid-like hollow structure, or a strip-like hollow structure, or a hollow structure in any other shape.

Furthermore the portion of the mode frame extending to the display area provides a less support force at the center of the display area, and thus is deformed more easily given the same force applied thereto, and provides a more support force on the edge of the display area, and thus is deformed less easily given the same force applied thereto.

Hereupon optionally in the display module above according to the embodiment of the application, the proportion of the hollow structure per unit area at the center of the display area can be less than the proportion of the hollow structure per unit area on the edge of the display area. Stated otherwise, the hollow structure at the center of the display area has a smaller hollow structure or has a smaller hollow area, and the structure on the edge of the display area has larger hollow structure or has a larger hollow area. In this way, the support structure can be deformed uniformly at respective positions given the same force applied thereto, thus resulting in a uniform variance in capacitance.

Optionally in the display module above according to the embodiment of the application, the support structure will not be limited to the portion of the mode frame extending to the display area, but can further include another layer structure. When the support structure is simply the portion of the mode frame extending to the display area, then the process of fabricating the display module may be further simplified.

For example, optionally in the display module above according to the embodiment of the application, the support structure can include at least one support body independent of each other located between the force sensing layer and the bottom side of the metal frame. Specifically the support body can be columnar, and configured to support the force sensing layer in a dot pattern. The support body can exist alone, that is, the support structure can include only the support body. Alternatively the support body can exist together with the portion of the mode frame extending to the display area, that is, the support structure includes both the support body, and the portion of the mode frame extending to the display area. At this time, the support body can provide a supplementary support of the portion of the mode frame extending to the center of the display area to thereby improve a support force at the center of the display area.

Optionally in the display module above according to the embodiment of the application, the number of support bodies per unit area at the center of the display area is more than the number of hollow structures per unit area on the edge of the display area. Stated otherwise, there are a larger number of support bodies at the center of the display area, and there are a smaller number of support bodies on the edge of the display area. In this way, the support structure is deformed uniformly at respective positions given the same force applied thereto, thus resulting in a uniform variance in capacitance.

Specifically in the display module above according to the embodiment of the application, the support structure will not be limited to any particular shape, thickness, and material, and the material of the support structure may be plastic or metal; and when the portion of the mode frame extending to the display area acts as the support structure, then the material of the support structure may be the same as the material of the mode frame, e.g., Polycarbonate (PC) or poly-methyl meth-acrylate (or organic glass (PMMA)).

Optionally in the display module above according to the embodiment of the application, the force sensing layer can include a plurality of sense electrodes, which are blocks and distributed in an array.

Specifically the shape, size, material, etc., of each sense electrode can be set as needed in reality, and will not be limited to any particular shape, size, material, etc. in the embodiment of the application as long as it can perform a force touch function. The size of each sense electrode can be made smaller to thereby improve the sensitivity to a force touch, so that the sense electrodes are distributed more densely in the display area, and for example, each sense electrode can be set corresponding to a respective pixel of the display panel in a one-to-one manner to thereby provide the sensitivity to a force touch at the level of a pixel. When the sensitivity is not required to be high, then each sense electrode may alternatively be set corresponding to a plurality of pixels of the display panel.

Optionally in the display module above according to the embodiment of the application, the sense electrodes can be transparent electrically-conductive films (ITO). The transparent electrically-conductive films are indium tin oxide (ITO) films. Meanwhile, the force sensing layer can also be referred to as an ITO sensor. The ITO sensor is electrically conductive and transparent, and cannot affect a display effect. Of course, the sense electrodes can alternatively be made of metal or another material, for example, although the embodiment of the application will not be limited thereto.

Optionally in the display module above according to the embodiment of the application, the display panel can include a liquid crystal display screen, and a backlight module located on the backside of the liquid crystal display screen, and meanwhile, the force sensing layer is located on the side of the backlight module facing the support structure.

Optionally in the display module above according to the embodiment of the application, the backlight module can specifically include a reflecting sheet, a light-guiding plate, and an optical film material stacked on each other, and meanwhile, the force sensing layer is located on the side of the reflecting sheet facing the support structure. Specifically the force sensing layer can be plated directly on the reflecting sheet to thereby further simplify a fabrication process. The optical film material can include in a number of structures, and for example, it can include three layers of a diffusing sheet, an upper prism sheet, and a lower prism sheet, or can include two layers or four layers, specifically as needed in reality, although the embodiment of the application will not be limited thereto.

It shall be noted that in the display module above according to the embodiment of the application, the force sensing layer can further include a metal line(s) connected with each sensing electrode, and the metal line(s) is configured to be connected with an Integrated Circuit (IC) as in the prior art, so a repeated description thereof will be omitted here.

Optionally in the display module above according to the embodiment of the application, the display panel can further include a light-emitting display screen, and meanwhile, the force sensing layer is located on the side of a base substrate of the light-emitting display screen facing the support structure. Furthermore the display panel can alternatively be another type of display panel, although the embodiment of the application will not be limited thereto.

Optionally in the display module above according to the embodiment of the application, the display module can further include a glass cover plate located on the display side of the display panel. Of course, the display module can further include another structure(s), and a repeated description thereof will be omitted here.

The display module above according to the embodiment of the application will be described below in details with reference to the drawings by way of an example.

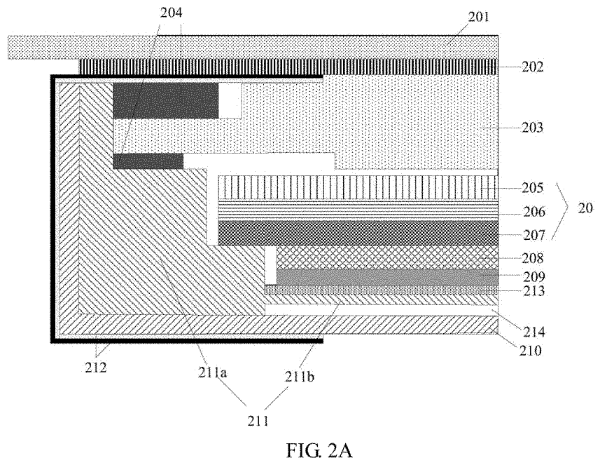

Referring to FIG. 2A, for example, an embodiment of the application provides a display module including: a metal frame 210, a mode frame 211 located in an accommodating chamber of the metal frame 210, a display panel 203, a buffer material 204, an optical film material 20, a light-guiding plate 208, a reflecting sheet 209, and a force sensing layer 213. The mode frame 211 includes two portions, i.e., a first portion 211a and a second portion 211b, where the second portion 211b is a support structure located below a display area of the display panel 203 to support overlying layers, and there is a gap 214 between the second portion 211b and the metal frame 210. Sealant 212 is arranged on the outside of the metal frame 210 to seal the display module so as to avoid light from being leaked. The sealant 212 may be structured in a plurality of layers as in the prior art, so a repeated description thereof will be omitted here. A cover plate 201 is arranged above the display panel 203, and optical adhesive 202 is arranged between the cover plate 201 and the display panel 203 to fix the cover plate 201.

In another example, referring to FIG. 2B, the support structure can further include a support body 211c in addition to FIG. 2A.

The optical film material 20 includes three layers, i.e., a diffusing sheet 205, an upper prism sheet 206, and a lower prism sheet 207 respectively from the top down.

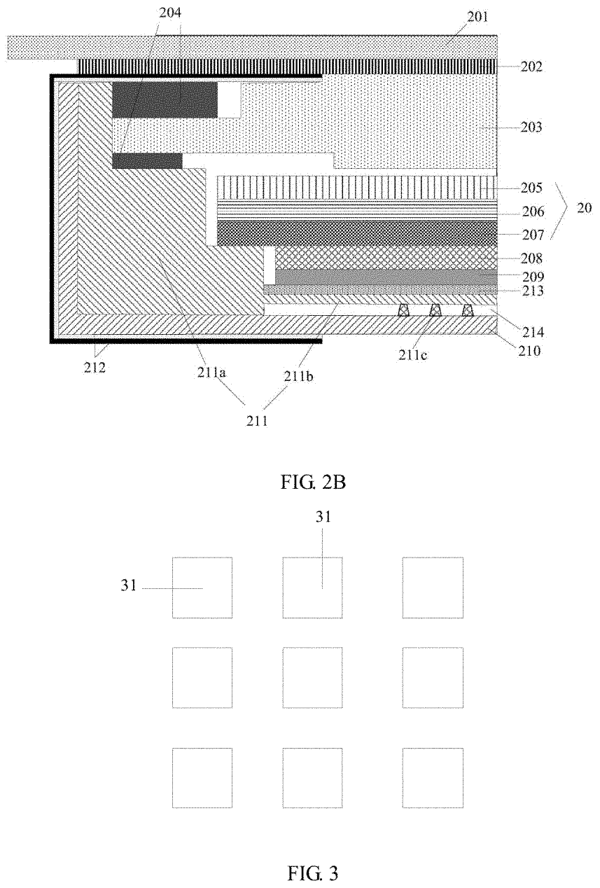

As illustrated in FIG. 3, the force sensing layer 213 includes a plurality of sense electrodes 31, which are blocks and distributed in an array, and the metal line(s) configured to connect each sense electrode with an IC (the metal line is not illustrated in FIG. 3).

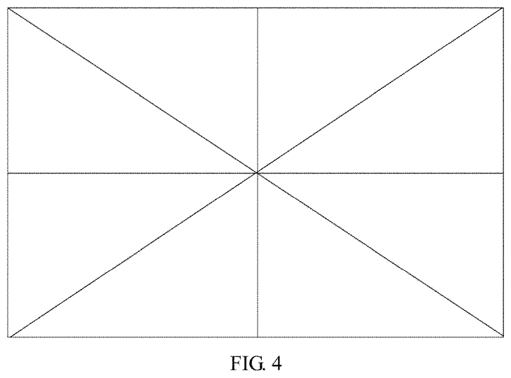

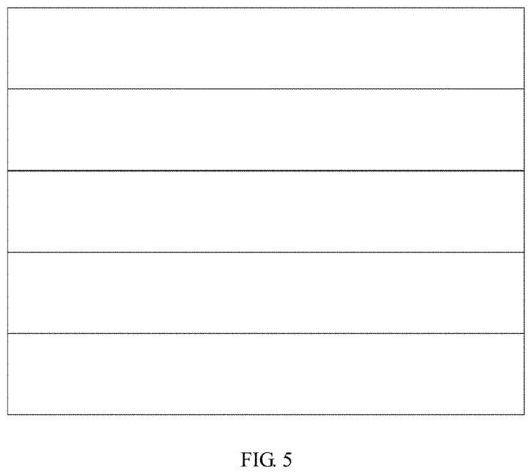

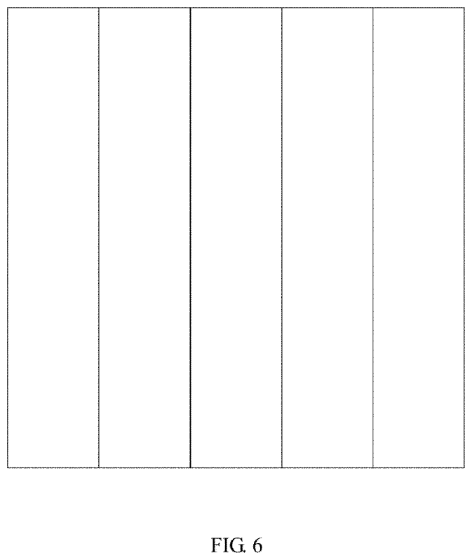

The second portion 211b of the mode frame (which acts as the support structure) can be structured in one of a number of hollow patterns as illustrated in FIG. 4, FIG. 5, and FIG. 6 in a top view. As illustrated in FIG. 4, the hollow structure can be a “ [symbol] ”-like hollow structure, and as illustrated in FIG. 5 and FIG. 6, the hollow structure can be a strip-like hollow structure. A blank area between lines is a hollow area, and the thickness of the line can be set as needed in reality, although the embodiment of the application will not be limited thereto.

The metal frame 210 is grounded as a reference layer (back cover GND) for a force touch, and the second portion 211b of the mode frame needs to have some rigidness, can support the force sensing layer and the overlying structure, and can be deformed in effect under the action of an acting force above the display panel (e.g., F=0 to ˜1000 g force), so that a capacitance C between the force sensing layer 213 and the metal frame 210 varies linearly, thus performing a force touch function in the display module.

The material of the metal frame 210 can be stainless steel (SUS304\SUS430\SGLC), or Al, etc., for example.

Based upon the same inventive idea, an embodiment of the application further provides a display device including the display panel according to the embodiment of the application. The display device can be a mobile phone, a TV set, a computer, a PAD, a digital photo frame, a navigator, or any other product with a display function and a function of sensing a force touch, for example.

In summary, in the technical solutions according to the embodiments of the application, the support structure configured to support the force sensing layer is additionally arranged in the accommodating chamber defined by the metal frame, and some gap between the force sensing layer and the metal frame varies with a varying force applied to the force sensing layer, so that a capacitance between the force sensing layer and the metal frame can vary under the action of a touch force to thereby perform a force touch function in the display module so as to simplify the process, to facilitate the integration of the industry, and to improve a good yield as a whole. Furthermore the force sensing layer is arranged on the backside of the display panel without affecting the brightness of the display module.

Evidently those skilled in the art can make various modifications and variations to the application without departing from the spirit and scope of the application. Thus the application is also intended to encompass these modifications and variations thereto so long as the modifications and variations come into the scope of the claims appended to the application and their equivalents.

1. A display module, comprising: a metal frame, a display panel in an accommodating chamber defined by the metal frame, a support structure located between a backside of the display panel and a bottom side of the metal frame, and a force sensing layer located on a side of the support structure facing the display panel, wherein:
a gap is provided between the force sensing layer and the metal frame, and the gap varies with a varying force applied to the force sensing layer.

2. The display module according to claim 1, further comprising a mode frame located in the accommodating chamber defined by the metal frame, and configured to support the display panel, wherein mode frame has a portion extending to a display area of the display panel, and the support structure comprises the portion of the mode frame extending to the display area.

3. The display module according to claim 2, wherein a gap is provided between the portion of the mode frame extending to the display area and the bottom side of the metal frame.

4. The display module according to claim 2, wherein the portion of the mode frame extending to the display area is a hollow structure.

5. The display module according to claim 3, wherein the hollow structure is a grid-like hollow structure, or a strip-like hollow structure.

6. The display module according to claim 5, wherein a proportion of the hollow structure per unit area at a center of the display area is less than the proportion of the hollow structure per unit area on an edge of the display area.

7. The display module according to claim 2, wherein a thickness of the portion of the mode frame extending to the display area is less than or equal to 0.1 mm.

8. The display module according to claim 1, wherein the support structure comprises at least one support body independent of each other located between the force sensing layer and the bottom side of the metal frame.

9. The display module according to claim 8, wherein the number of support bodies per unit area at a center of the display area is more than the number of hollow structures per unit area on an edge of the display area.

10. The display module according to claim 1, wherein the force sensing layer comprises a plurality of sense electrodes, which are blocks and distributed in an array.

11. The display module according to claim 10, wherein the sense electrodes are transparent electrically-conductive films

12. The display module according to claim 1, wherein the metal frame is grounded.

13. The display module according to claim 1, wherein the display panel comprises a liquid crystal display screen, and a backlight module located on a backside of the liquid crystal display screen, and the force sensing layer is located on a side of the backlight module facing the support structure.

14. The display module according to claim 13, wherein the backlight module comprises a reflecting sheet, a light-guiding plate, and an optical film material stacked on each other, and the force sensing layer is located on a side of the reflecting sheet facing the support structure.

15. The display module according to claim 1, wherein the display panel comprises a light-emitting display screen, and the force sensing layer is located on a side of a base substrate of the light-emitting display screen facing the support structure.

16. A display device, comprising a display module, wherein the display module comprises: a metal frame, a display panel in an accommodating chamber defined by the metal frame, a support structure located between a backside of the display panel and a bottom side of the metal frame, and a force sensing layer located on a side of the support structure facing the display panel, wherein:
a gap is provided between the force sensing layer and the metal frame, and the gap varies with a varying force applied to the force sensing layer.

17. The display module according to claim 11, wherein the transparent electrically-conductive films are indium tin oxide (ITO) films.
